(19) United States
(12) Patent Application Publication
(10) Pub. No.: US 2003/0121053 A1
(43) Pub. Date: Jun. 26, 2003

(54) Video distribution test system for evaluating image quality by determining spread of frame loss within refreshment interval

(75) Inventor: Yoshizou Honda, Tokyo (JP)

Correspondence Address: COHEN, PONTANI, LIEBERMAN & PAVANE, 551 FIFTH AVENUE, SUITE 1210, NEW YORK, NY, 10176, US

(73) Assignee: Ando Electric Co., Ltd., Tokyo (JP)

(21) Appl. No.: 10/320,276

(22) Filed: Dec. 16, 2002

(30) Foreign Application Priority Data
Dec. 25, 2001 (JP) 2001-391370

(51) Int. Cl. H04L 1/22; H04B 1/74; H02H 3/05; H05K 10/00; H03K 19/003; H04N 7/173

(52) U.S. Cl. 725/107; 725/116; 714/1; 714/6; 714/47; 714/48

(57) ABSTRACT

A video distribution test system for performing simplified measurement under assumed conditions closer to the actual situation, and for performing tests for effective applications. The system includes a video packet simulator for defining different packet loss rates and simulating packet loss in video packets transmitted from the video distributing server for each packet loss rate, so as to produce defective video streams and evaluate an image quality of each defective stream, and producing a conversion table between the packet loss rate and the image quality; a pseudo-load generator for issuing pseudo-distribution requests from clients to the video distributing server; a packet quality monitor for receiving video packets from the server and calculating a packet loss rate for each client by detecting packet loss; and an image quality evaluating section for evaluating the image quality for each client based on the calculated packet loss rate and the conversion table.

### BACKGROUND OF THE INVENTION

1. Field of the Invention

The present invention relates to a video distribution test system, and in particular, relates to a test system for testing the quality of video distribution of a device for performing streaming distribution of digital video codes on a packet exchange network.

2. Description of the Related Art

Digital video images consist of a series of moment images called frames. The screen of a digital video display consists of multiple points on a lattice, which are called pixels. Each frame consists of digital data corresponding to the pixels, and each digital data indicates the color, brightness, or gradation value of the corresponding pixel. The digital video codes have a form of the bit sequence produced by compressing the original video data, and the bit sequence may be called a video stream.

The known international standards relating to the video codes are (i) MPEG-2 (MPEG: moving picture experts group) and MPEG-4 based on ISO (international organization for standardization) and IEC (international electrotechnical commission) which are international standardizing organizations, that is, MPEG-2 is defined as ISO/IEC-13818, and MPEG-4 is defined as ISO/IEC-14496, and (ii) H.261 and H263 based on ITU (international telecommunication union) recommendation, among others.

As an example of the video data coding methods used in the international standards, the interframe prediction coding method is known. In this method, differences between two frames which are close to each other are encoded and transmitted, and in the receiving side, only the difference is encoded and is added to a frame which has already been decoded. Statistically, such adjacent frames tend to include the same objects or backgrounds; that is, in most cases, the adjacent frames resemble each other and have only slight differences. Therefore, data can be compressed by actually encoding only such a slight difference. Such a method in which a portion of the already-decoded frame is used so as to decode a new frame (which has not yet been decoded) is called a “reference”, and the frame referred to is called a reference frame.

However, the interframe prediction coding has a defect which is common in prediction coding methods. That is, when the frame referred to has not been accurately decoded, the frame which has been decoded using the above frame also contains errors. Moreover, the error spreads in series while the reference relationship is relayed.

In order to terminate the reference relationship between the frames, a method is known in which the codes are cut off at a specific position, and the codes after the position are decoded by only referring to the codes after the position, without referring to the codes before the position. Such a position (i.e., frame) is defined at specific intervals.

Such a function for finishing the reference so as to remove errors is called “refreshment”, and the frame decoded using only the codes in its own frame is called “intraframe” (abbreviated as “I-frame” hereinbelow). If refreshment is executed one or two times per second, or one time per one or two seconds, it will seem to the viewer that the degraded image is momentarily restored; thus, this method can effectively improve the visual experience of the viewer.

The frame decoded by referring to immediately before that frame is called the “P-frame”, and the frame decoded by referring to the frame immediately before that frame and immediately after that frame is called the “B-frame”. When the B-frame is decoded, the frame immediately after is first decoded.

The frame prediction type indicates which reference is used for each kind of frame. Typically, a P-frame is decoded by referring to an I- or P-frame immediately before, and a B-frame is decoded by referring to I- or P-frames immediately before and after.

An example is shown in FIG. 4, in which I, B, P, B, P, I, and B-frames are displayed in turn, and each arrow indicates the reference relationship between the frames. In this case, refreshment is performed at the last I-frame.

Each frame in the video stream consists of a frame header and frame data. The frame header includes a code indicating the frame prediction type. The video stream corresponding to the frames in FIG. 4 is shown in FIG. 5. Each hatched portion indicates the frame header of each frame.

In the known video streaming method, received video codes are decoded and displayed in turn before the transmission of all video codes is completed. Therefore, in video streaming, the succeeding video codes are decoded and displayed at specific intervals in the video data receiver, so as to reproduce video image having smooth motion. When each interval has passed, video codes, which have not been received before the specific time, are abandoned, so as to start decoding and displaying of the following codes.

Accordingly, if a transmission error, loss or delay of transmitted data, or the like occurs, the corresponding image cannot be accurately reproduced at the data receiving side. In this case, an imperfect image is displayed, or the frame which was correctly decoded last is re-displayed instead of displaying the current frame. Therefore, to the viewer, the motion may stop or may be jerky or awkward. Such degradation in the quality of received video image is called display skip or display freeze of the frame (simply called “display skip” hereinbelow). Here, such degradation is inherited to the next frame which refers to the frame which was not correctly decoded.

In the following explanations, the display skip of the frame and its inheritance are focused on among several kinds of degradation in the quality of the received video image, which is caused by the transmission error, data loss or delay, or the like. The following phenomena are also typical examples of degradation: (i) the video codes cannot be decoded for a long time, and (ii) a partial image loss is temporarily produced in the image. However, these phenomena are suitably evaluated using methods different from the method related to the present invention, and are not explained here.

Recently, according to the spread of LANs (local area network) and the Internet, video streaming on a packet exchange network based on IP (Internet protocol) has prevailed, and transmission capacity, cost, and quality are considerably improved.

For example, as for the quality, even if some bits in transmitted data are errors or some packets are abandoned or lost, compensation such as error correction or retransmission of packets is performed. In addition, effective video distribution methods have been recently employed, in which (i) the transmission rate of video codes is controlled according to the packet loss rate calculated before the packets are introduced into the packet network, or according to the traffic, or (iii) a buffer is provided in the packet receiving section and a time difference is secured between the reception and the starting of the encoding, so as to complete resending of lost packets.

In order to realize smooth video reproduction, packets which have not been transmitted and also retransmitted for a specific time are abandoned. However, according to the above compensation method, the rate of the packets which have not been correctly received by the decoding section, that is, the packet loss rate of the remaining packets is very low. Typically, in a network having a (normal) packet loss rate of approximately 1%, the packet loss rate of the remaining packets can be less than approximately 0.01 to 0.1%.

As explained above, in high-quality video distribution, display skip of a video frame and its inheritance or spread, caused by loss of the remaining packets, is a main cause for degrading the quality of video distribution. Therefore, the packet loss rate of the remaining packets is very important for testing or evaluating the quality of distributed video images.

In video streaming, a client issues a distribution request to the video distributing server having the content, and video codes transmitted from the video distributing server are received by the client. Here, a number of clients access the same video distributing server on a network; therefore, the video distributing server distributes the same content or different content to the clients in parallel.

Generally, the amount of video codes is very large, and the processing capability of the video distributing server has a limit. Therefore, when the number of clients to which video codes are transmitted in parallel is increased, the quality of distribution to some clients may be degraded or the distribution itself may be stopped. Therefore, it is necessary to perform in advance, a test for determining the number of clients to which video codes can be simultaneously distributed in parallel (called the “number of simultaneous clients” hereinbelow), so as to determine an acceptable number of clients. With such an acceptable number, degradation of the quality of distribution can be prevented in the actual distribution service by receiving distribution requests within the acceptable number. Such a test is called a video distributing server load test.

In conventional video distributing server load tests, a few tens of computers are provided as clients, and a plurality of clients simultaneously access the video distributing server (i.e., an object to be tested), so as to check whether the distribution service is normally performed to each client.

However, in order to perform the test by using a few tens of computers, a great deal of preparation, relating to arrangement, setting, connection, installation, starting, operation, place, electrical power, air conditioning, and the like, is necessary. However, the frequency of use of such an arrangement for the test is relatively small, and the efficiency of the system is therefore low.

In addition, the amount of the received video encoded data, which is to be decoded and displayed, is very large. Therefore, even if a plurality of distribution requesting programs or data receiving programs are loaded in parallel, approximately a dozen parallel operations is the actual limit for a single computer. Accordingly, even with a few tens of such computers, the total number of parallel operations, which can be simultaneously performed, is a few hundred or the like. Therefore, in conventional systems, it is difficult to perform the test when the number of simultaneous clients is 1000 or greater.

Therefore, it is necessary to increase the number of simultaneous parallel operations or decrease the number of the computers. In consideration of this situation, the inventor of the present application has made an invention relating to an access generator for testing the video distributing server and a video distributing server testing method. In this invention, a load generating section is provided, in which many pseudo-client software programs (called “pseudo-clients” hereinbelow), which are low loads for the computers, are operated. That is, low-load programs are operated instead of the distribution requesting programs and the video data receiving programs.

In addition, when an excess load is imposed on the video distributing server, the quality of distribution to some of the simultaneous clients may be degraded. In such a case, it is not easy to predict for which client the quality of distribution will degrade first. Therefore, it is necessary to check the quality of distributed images for all of the simultaneous clients. In consideration of this necessity, the inventor of the present application also provided an invention relating to the video distribution test system.

In this invention, in addition to the above-explained pseudo-clients, a quality monitor is provided for evaluating the image quality, where loss or a defect in the video frame header is regarded as the main cause of the display skip. This invention also provides a means for determining a relationship between the quality of the packets and the image quality by using a pseudo-network for controlling the packet loss rate, so as to determine the image quality from the quality of the packets.

The above image quality relates to the display skip of the video frame and its inheritance, and the quality of the packets relates to the packet loss rate, the packet delay and delay jitter, the throughput, and the like.

An embodiment of the video distribution test system which the inventor invented is shown in FIG. 3.

In the figure, when the clients 202 request distribution to the video distributing server 201 via the distribution and synthesis device 302 (such as a HUB used in an LAN), the server distributes video codes. In this process, the pseudo-network 303 changes the packet loss rate so as to define several packet loss rates. According to such different packet loss rates, the quality monitor 301 evaluates the image quality at the receiving side by employing values indicating the image quality, thereby obtaining a conversion table between the packet loss rate and the image quality.

In the next step, a number of pseudo-clients issue distribution requests from the pseudo-load generator 401 to the video distributing server 201, and the video distributing server 201 transmits a number of video streams. The video streams are received by the packet quality monitor 103 via the packet filter 1031.

A sequence number is assigned to each video packet distributed to each client, and the sequence number extracting section 1032 extracts the sequence number, so as to detect lost (or defective) packets. If there is a packet delay in comparison with the defined time stamp, the relevant packet is also regarded as a lost packet.

A value indicating the image quality for each client can be obtained based on the calculated packet loss rate and the above-explained conversion table.

However, in the conventional video distribution test system, the relationship between the quality of the packets and the image quality is determined based on actual measurements using a pseudo-network, as explained above. The pseudo-network for controlling the packet loss rate has a high-speed processing capability for controlling and discriminating the packets; thus, the pseudo-network is generally an expensive experimental device.

In addition, it is necessary to send video codes at several packet loss rates and to evaluate the image quality for each packet loss rate based on the actual measurement; thus, the operation of the measurement is complicated and time consuming. Therefore, an evaluation method using a simpler system which can be more simply operated is required.

The conventional video distribution test system also has a quality monitor for evaluating the frame loss rate by regarding the defective video frame header as the main cause of the display skip; however, the inheritance or spread of degradation of the quality, caused by the reference of the frame, is not considered. Therefore, if an I-frame is lost, the relevant degradation spreads to the next I-frame in the actual operation; however, in the conventional test, less degradation is evaluated.

If the cause of degradation of the image quality is limited to the loss of the remaining packets as explained above, results of decoding of the video stream including lost packets, which is input into the decoding section, indicate the image quality.

Conventionally, for generalization, N possible portions, at which a loss may be produced in the video stream, are assumed in consideration of the bit error, frequent packet loss, long refreshment interval, and the like (N is a positive integer). However, N is very large so as to decode and reproduce the image corresponding to each defective video stream.

In addition, decoding is relatively large-scale processing; thus, ordinary low-priced computers can be used for software decoding of a few streams at best. When N is much greater, it is actually difficult to perform the simulation using such ordinary computers.

### SUMMARY OF THE INVENTION

In consideration of the above circumstances, an object of the present invention is to provide a video distribution test system for performing simplified measurement under assumed conditions closer to the actual situation, and for performing tests for effective applications.

Therefore, the present invention provides a video distribution test system provided between clients and a video distributing server, comprising:

a video packet simulator for defining different packet loss rates and simulating packet loss in video packets transmitted from the video distributing server for each packet loss rate, so as to produce defective video streams and evaluate an image quality of each defective stream, and producing a conversion table between the packet loss rate and the image quality;

a pseudo-load generator for issuing pseudo-distribution requests from a plurality of clients to the video distributing server;

a packet quality monitor for receiving video packets transmitted from the video distributing server in response to the pseudo-distribution requests, and calculating and outputting a packet loss rate for each client by detecting packet loss; and

an image quality evaluating section for evaluating the image quality for each client based on the packet loss rate output from the packet quality monitor and the conversion table.

According to this structure, the image quality can be determined based on the results of the simulation, and several image qualities can be simultaneously determined according to simple measurement.

As a typical example, the video packet simulator divides a video stream of the video packets into streams at refreshment intervals defined for an interframe reference relationship, and performs the above simulation of packet loss for each divided stream. Accordingly, the amount of simulating calculation can be reduced, thereby performing the simulation using ordinary computers.

As another typical example, the video packet simulator:

determines frame loss by checking video frame headers in each defective video stream;

detects a reference frame which is referred to by each defective frame by extracting a frame prediction type in the video frame header of the defective frame and determines whether the reference frame is also a defective frame;

determines frame loss caused by inheritance due to reference by each defective frame to the defective reference frame; and

outputs the image quality as a frame loss rate of defective frames in all frames.

Accordingly, a frame loss rate closer to the actual value can be evaluated by performing a simulation which has a small amount of calculation.

The present invention also provides a video distribution test system provided between clients and a video distributing server, comprising:

a pseudo-load generator for issuing pseudo-distribution requests from a plurality of clients to the video distributing server;

a packet quality monitor for:

receiving video packets transmitted from the video distributing server in response to the pseudo-distribution requests;

detecting frame loss by checking video frame headers in the video packets for each client;

extracting a frame prediction type in the video frame header of each defective frame so as to detect a reference frame which is referred to by the defective frame, and determining whether the reference frame is also a defective frame; and

determining frame loss caused by inheritance due to reference by each defective frame to the defective reference frame;

an image quality evaluating section for evaluating the image quality for each client, based on the frame loss determined for each client by the packet quality monitor.

According to this structure, a frame loss rate closer to the actual value can be evaluated by performing a simple header-detecting operation.

### BRIEF DESCRIPTION OF THE DRAWINGS

FIG. 1 is a diagram showing the structure of the video distribution test system as the first embodiment of the present invention.

FIG. 2 is a diagram showing the structure of the video distribution test system as the second embodiment of the present invention.

FIG. 3 is a diagram showing the structure of a conventional video distribution test system.

FIG. 4 is a diagram for explaining the video frame prediction and the refreshment of a video stream.

FIG. 5 is a diagram showing packets and the video frame header of each packet.

### DESCRIPTION OF THE PREFERRED EMBODIMENTS

As explained above, if the simulation is performed in an environment close to the actual environment, by using a high-quality packet exchange network and by employing the error correction, retransmission, or buffering, then the packet loss rate of the remaining packets, which are not normally input into the decoding section, is very small.

The packet loss spreads only within an interval from refreshment and the next refreshment and is determined only by checking the frame header. Therefore, the scale of the simulation processing is a few hundredths to a few thousandths as much as the scale of the decoding process; thus, the simulation has a scale suitable for actual processing. That is, the simulation for a few hundreds to a few thousands of streams which should be simultaneously transmitted can be performed for a time approximately as much as the time of the video corresponding to the streams, by using a computer having a processing capability of simultaneously decoding a few streams.

This will be further explained by employing specific values.

It is assumed that the packet loss rate of the remaining packets is 0.01%. As explained above, the display skip spreads only within a refreshment interval between refreshment and the next refreshment, where the interval is approximately a large fraction of a second to several seconds. If the transmission rate of the video code is 1000 kbps to 1 Mbps, the number of packets transmitted in the refreshment interval is a few kB to a few hundred kB. Here, the packet length is a few tens of B to 1 kB; thus, the number of packets in the refreshment interval is approximately a few packets to a few tens of thousands of packets.

According to the above calculation, in the refreshment interval, the number of the remaining packets is 0.01 to 1 on average. If the packet loss rate of the remaining packets among 1000 packets is 0.01%, the probability that the packet loss is any one packet or less is approximately 99%. Therefore, the typical quality of packets is defined as “no loss” or “loss of 1 remaining packet”.

In this case, the image quality for 1000 streams, each having a single packet loss, may be evaluated by performing the simulation in which the frame header and the spread of the loss are checked. The decoding itself is not executed; thus, the simulation can be executed for a time approximately as much as the time of the video corresponding to the video streams.

Hereinafter, embodiments according to the present invention will be explained with reference to the drawings.

First Embodiment

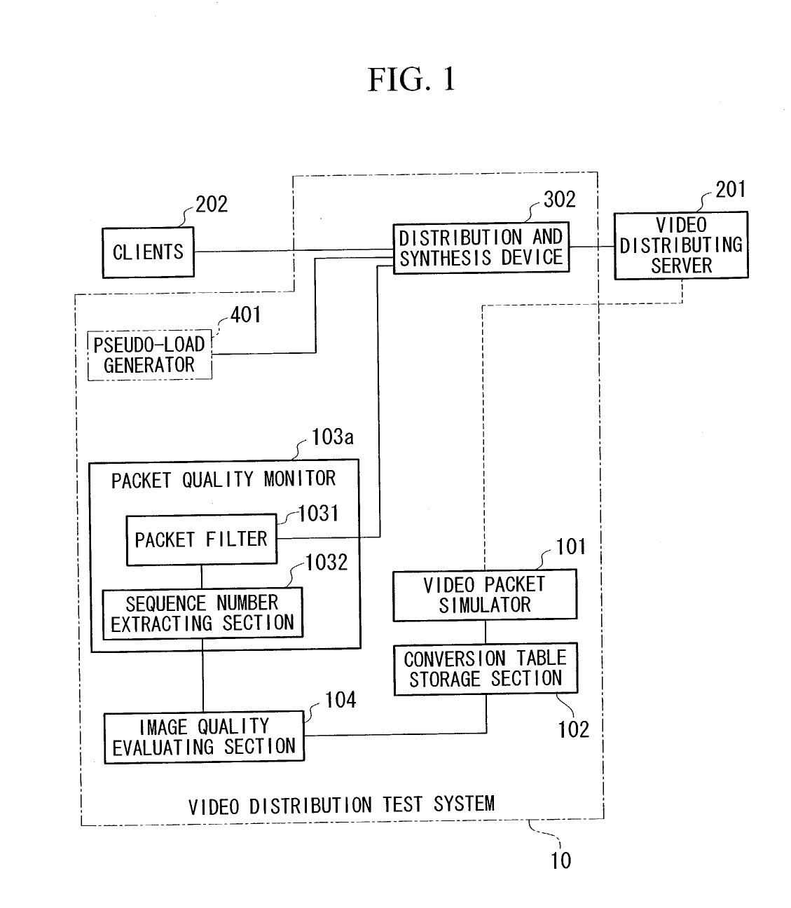

FIG. 1 is a diagram showing the structure of the video distribution test system 10 as the first embodiment of the present invention. The structure and operation of the video distribution test system 10 will be explained with reference to FIG. 1.

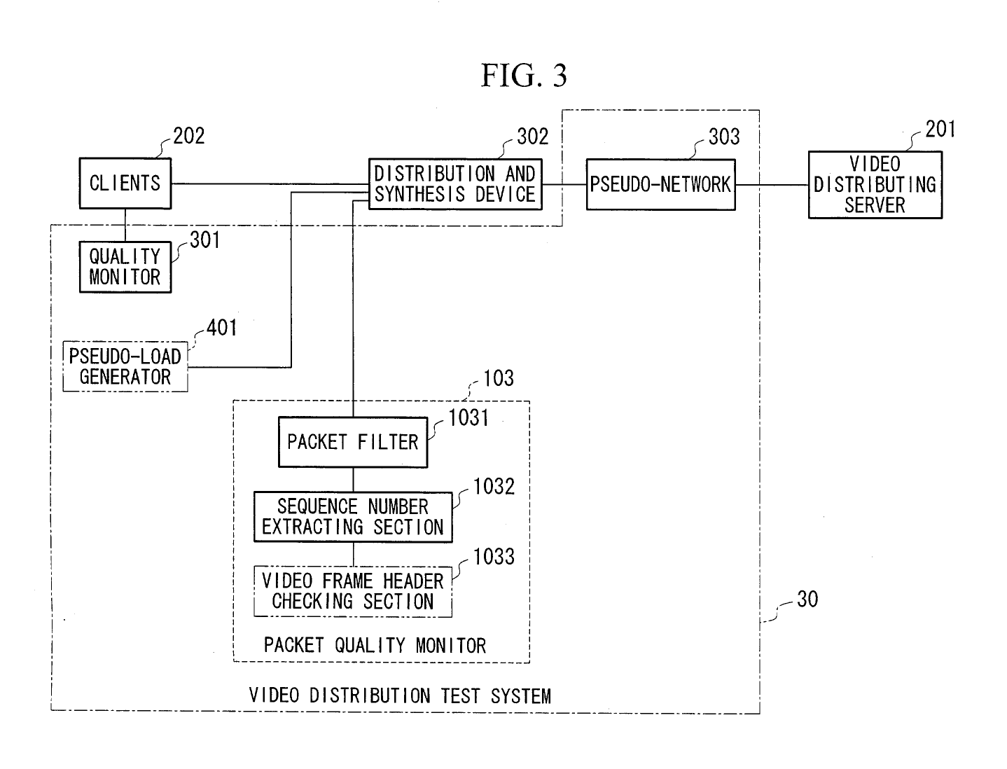

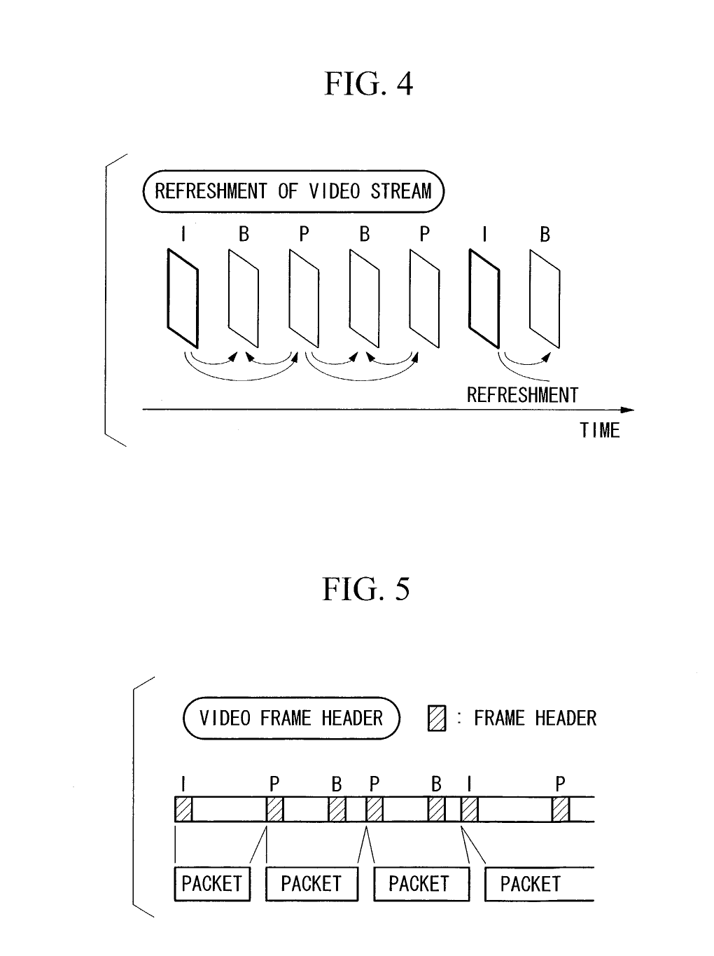

As shown in FIG. 1, the video distribution test system 10 employs a video packet simulator 101 without employing a pseudo-network as employed in the above-explained conventional example. In FIG. 1, parts identical to those in FIG. 3 are given identical reference numerals, and explanations thereof are omitted or simplified.

In FIG. 1, the video distributing server 201 transmits video packets to the video packet simulator 101. The video packet simulator 101 divides video frames in each video stream at refreshment intervals and extracts each divided stream corresponding to each refreshment interval. As for each divided stream, the video packet simulator 101 defines several kinds of packet loss rates and calculates the packet loss rate of the remaining packets according to the compensation method such as retransmission or buffering. The video packet simulator 101 then simulates a packet-unit loss for each packet loss rate so as to produce a defective video stream.

The video packet simulator 101 then examines video frame headers in the defective video stream so as to detect each defective frame. The video packet simulator 101 also extracts the frame prediction type from the frame header, and if the reference frame which the defective frame refers to is lost (or defective), it is determined that the defective frame is a lost frame due to the spread of the loss. Accordingly, the video packet simulator 101 produces and outputs a conversion table between the packet loss rate and the frame loss rate. This conversion table is stored in the conversion table storage section 102.

When the clients 202 or the pseudo-load generator 401 issues distribution requests to the video distributing server 201, the video distributing server 201 transmits video streams (to a number of clients). The packet quality monitor 103a receives the video streams via the packet filter 1031.

The sequence number extracting section 1032 extracts the sequence numbers appended to the video packets transmitted to each client, so as to detect packet loss based on the absence of any sequence number. If a packet which is delayed in comparison with the specific time stamp, the packet is also regarded as a lost packet.

The packet quality monitor 103a calculates and outputs the packet loss rate based on the detected packet loss, and the image quality evaluating section 104 obtains a value indicating the image quality (i.e., frame loss rate) for each client, based on the packet loss rate and the above conversion table.

Second Embodiment

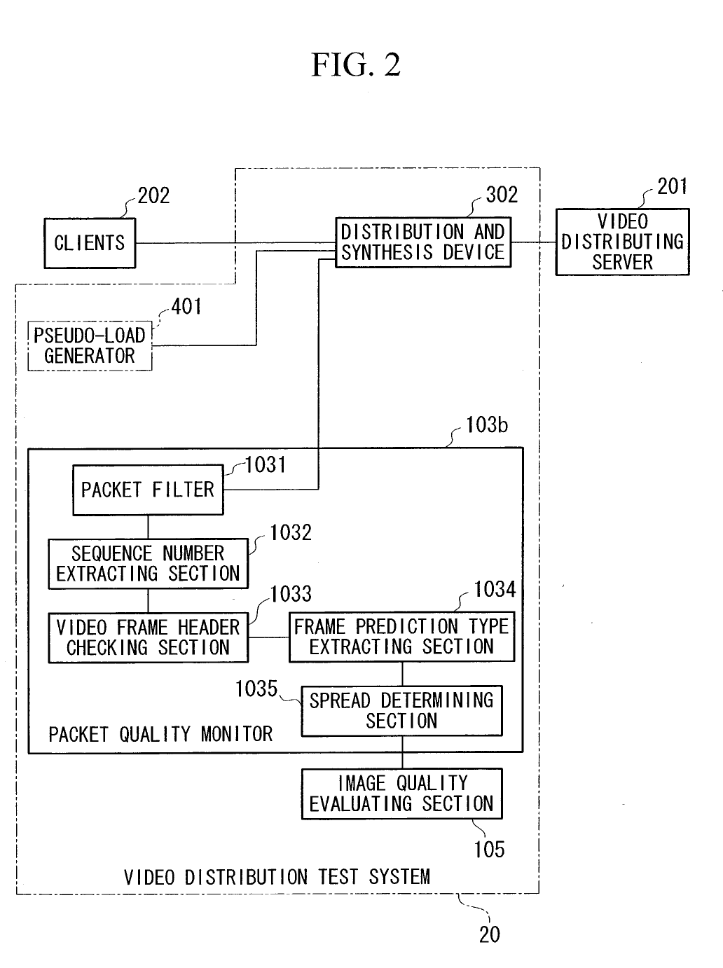

FIG. 2 is a diagram showing the structure of the video distribution test system 20 according to the present invention. The structure and operation of the video distribution test system 20 will be explained with reference to FIG. 2.

In FIG. 2, parts identical to those in FIG. 1 are given identical or corresponding reference numerals, and the explanation thereof are omitted or simplified.

As shown in FIG. 2, the video distribution test system of the present embodiment does not employ a pseudo-network (which is employed in the conventional example), but employs a frame prediction type extracting section 1034 and a spread determining section 1035.

In FIG. 2, the clients 202 or the pseudo-load generator 401 issues distribution requests to the video distributing server 201, and the video distributing server 201 transmits video streams.

The packet quality monitor 103b receives the video streams via the packet filter 1031. The sequence number extracting section 1032 extracts the sequence numbers appended to the video packets transmitted to each client, so as to detect the packet loss based on the absence of any sequence number. If a packet which is delayed in comparison with the specific time stamp, the packet is also determined to be a lost packet.

The video frame header checking section 1033 checks the frame header of each video frame, so as to detect each defective frame. The frame prediction type extracting section 1034 extracts the frame prediction type from the video frame header. If the reference frame which is referred to by the defective frame is lost, the spread determining section 1035 determines that the defective frame is lost due to the spread of the frame loss, and as a result, the image quality evaluating section 105 evaluates the frame loss rate for each client.

The present invention can also be applied to tests of video codes similar to those based on the coding methods employed by the above-explained international standards.

What is claimed is:

1. A video distribution test system provided between clients and a video distributing server, comprising:
a video packet simulator for defining different packet loss rates and simulating packet loss in video packets transmitted from the video distributing server for each packet loss rate, so as to produce defective video streams and evaluate an image quality of each defective stream, and producing a conversion table between the packet loss rate and the image quality;
a pseudo-load generator for issuing pseudo-distribution requests from a plurality of clients to the video distributing server;
a packet quality monitor for receiving video packets transmitted from the video distributing server in response to the pseudo-distribution requests, and calculating and outputting a packet loss rate for each client by detecting packet loss; and
an image quality evaluating section for evaluating the image quality for each client based on the packet loss rate output from the packet quality monitor and the conversion table.

2. A load test system as claimed in claim 1, wherein the video packet simulator divides a video stream of the video packets into streams at refreshment intervals defined for an interframe reference relationship, and performs the above simulation of packet loss for each divided stream.

3. A load test system as claimed in claim 1, wherein the video packet simulator:
determines frame loss by checking video frame headers in each defective video stream;
detects a reference frame which is referred to by each defective frame by extracting a frame prediction type in the video frame header of the defective frame and determines whether the reference frame is also a defective frame;
determines frame loss caused by inheritance due to reference by each defective frame to the defective reference frame; and
outputs the image quality as a frame loss rate of defective frames in all frames.

4. A video distribution test system provided between clients and a video distributing server, comprising:
a pseudo-load generator for issuing pseudo-distribution requests from a plurality of clients to the video distributing server;
a packet quality monitor for:
receiving video packets transmitted from the video distributing server in response to the pseudo-distribution requests;
detecting frame loss by checking video frame headers in the video packets for each client;
extracting a frame prediction type in the video frame header of each defective frame so as to detect a reference frame which is referred to by the defective frame, and determining whether the reference frame is also a defective frame; and
determining frame loss caused by inheritance due to reference by each defective frame to the defective reference frame;
an image quality evaluating section for evaluating the image quality for each client, based on the frame loss determined for each client by the packet quality monitor.
